(19) United States
(12) Patent Application Publication
(10) Pub. No.: US 2006/0266544 A1
(43) Pub. Date: Nov. 30, 2006

(54) Printed circuit board (PCB) with electrostatic discharge protection

(75) Inventors: Chia-Hsin Tung, Kaohsiung City (TW); Jim Lin, Nan Tou Hsien (TW); Chi-Wei Liu, Chung Ho City (TW); How-Ping Lee, Taipei (TW)

Correspondence Address: LADAS & PARRY, 26 WEST 61ST STREET, NEW YORK, NY, 10023, US

(73) Assignee: BENQ CORPORATION

(21) Appl. No.: 11/439,790

(22) Filed: May 24, 2006

(30) Foreign Application Priority Data
May 24, 2005 (TW) 94116929

(51) Int. Cl. H05K 1/11; H05K 1/09

(52) U.S. Cl. 174/250; 174/255

(57) ABSTRACT

A printed circuit board (PCB) with electrostatic discharge protection includes at least a lead wire having a first edge with an exposed copper, and a ground wire having a second edge with another exposed copper, in which the first edge faces the second edge with a predetermined spacing. By providing the pair of the first and the second edges, electrostatic discharge of the PCB can be arbitrarily carried out between the lead wire and the ground wire.

### FIELD OF THE INVENTION

The present invention relates to a printed circuit board (PCB) with electrostatic discharge protection, more particularly to the PCB having an edge with an exposed copper for providing the electrostatic discharge function to the PCB.

### BACKGROUND OF THE INVENTION

The electrostatic discharge (ESD) is defined that an accumulated electrostatic charge is discharged from a high electrostatic charge collection area to an opposite electric charge collection area or a low electric charge collection area. Also, the electrostatic discharge is known in the art as one of primary destroy factors, which cause majority electronic components or the electronic system to be electrically overstressed. The destroy from overstressing may lead to permanent destruction or unstable operation to the semiconductor elements. As a clear consequence, an integrated circuit having overstressed elements may have difficulty to continue its normal operation. Also, the accumulation of the electrostatic charges as well as the resulting destruction upon the elements are implicit and, definitely, not easy to be located.

Along with the development of the chip technology, it is inevitable for the electronic products (for example cellular phone or PDA) to face the miniaturization problems. In a compact or small-size electronic product such as a cellular phone, the electrostatic discharge becomes more notable and lethal for its internal elements are easier to accumulate electrostatic charges excessively and to cause the elements vulnerable.

To avoid possible electrostatic discharge damages, a typical method is to promote the element itself in electrostatic discharge protection ability. Such a method usually aims at the electric circuit design. Another method to protect the element from electrostatic discharge is to prevent the element from electrostatic charge accumulation. To lessen the accumulation of the static charges, devices based on the point discharge principle are usually used. For example, eliminators located at wing tips or tails of an airplane and the lightning rods mounted to roofs of buildings are two of those most typical applications.

FIG. 1 shows a cross-section view of a conventional a printed circuit board with electrostatic discharge protection, detailed in Publication number 566840 of Taiwan patents, in which the printed circuit board includes a lead wire level 11, a plug-in type electric conduction element 12, a ground level 13, an insulation level 14 and a through hole 15.

The lead wire level 11 allows the electric current to pass. The plug-in type electric conduction element 12 is connected to the lead wire level 11, and has a lower edge for point discharging. The ground level 13 as a conduction material locates near the edge of the element 12 for receiving the discharge from the edge of the element 12. The insulation level 14 forms between the lead wire level 11 and the ground level 13 so as to separates the electric connection in between. The through hole 15 formed in the insulation level 14 is used to mount the plug-in type electric conduction element 12 with its edge facing the ground level 13. By providing the electrostatic discharge mechanism formed by the element 12 connected with the lead wire level 11, the ground level 13, and the spacing between the edge of the element 12 and the ground level 13, the printed circuit board can have a substantial function to discharge the accumulated charge and thus to prevent the electronic elements and circuits from possible electrostatic damage.

Though the aforesaid mechanism can prevent the printed circuit board from electrostatic damage, the through hole 15 for accommodating the element 12 and the formation of the complete mechanism in the electric circuit make the fabrication of the printed circuit board complicated and costly.

### SUMMARY OF THE INVENTION

The object of the present invention is to provide a printed circuit board with electrostatic discharge protection, in which a pair of edges, each having an exposed copper, are used to discharge electrostatic charges.

In accordance with the present invention, the printed circuit board with electrostatic discharge protection includes at least a lead wire having a first edge with edgean exposed copper, and a ground wire having a second edge with another exposed copper, in which the first edge spaces the second edge by a predetermined spacing. By providing the pair of the first and the second edges, electrostatic discharge of the PCB can be arbitrarily carried out in between. Preferably, the spacing between the first edge and the second edge is approximately ranged from 0.05 mm to 0.1 mm. The edges, either the first edge or the second edge, can be shaped as a triangle, a lanceolar, and any shape that provides a tip for electrostatic discharging.

In another aspect of the present invention, a printed circuit board with electrostatic discharge protection includes at least a lead wire having a first dentiform edge with an exposed copper, and a ground wire having a second dentiform edge with another exposed copper, in which the first edge distances the second dentiform edge with a predetermined spacing. By providing the pair of the first and the second dentiform edges, electrostatic discharge of the PCB can be arbitrarily carried out between the lead wire and the ground wire.

### BRIEF DESCRIPTION OF THE DRAWINGS

Other features and advantages of this invention will become more apparent in the following detailed description of the preferred embodiments of this invention, with reference to the accompanying drawings, in which:

FIG. 1 is a cross-section view of a conventional printed circuit board with electrostatic discharge protection;

FIG. 2 shows a printed circuit board with electrostatic discharge protection in accordance with the present invention;

FIG. 2a shows a printed circuit board with electrostatic discharge protection whose edge shape is a triangle;

FIG. 2b shows a printed circuit board with electrostatic discharge protection whose edge shape is a lanceolar; and

FIG. 2c shows a printed circuit board with electrostatic discharge protection whose edge shapes is a dentiform.

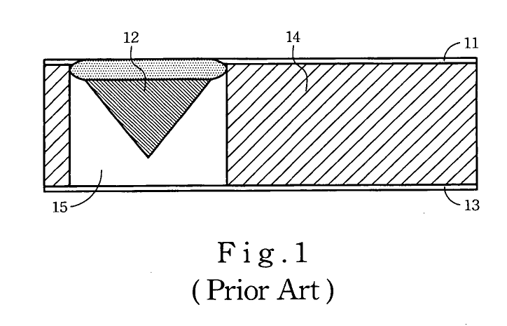

### DETAILED DESCCRIPTIONS OF THE PREFERRED EMBODIMENT

This invention uses a layout edge with an exposed copper on the printed circuit board to carry out the point discharge principle.

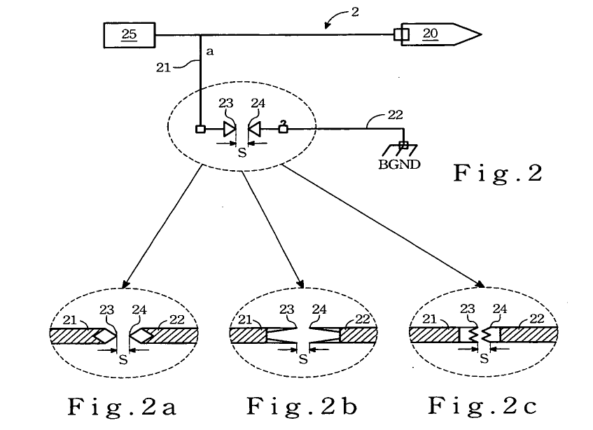

Referring to FIG. 2, a printed circuit board with electrostatic discharge protection includes an internal element 20, a lead wire 21, a ground wire 22, a first edge 23, a second edge 24 ,and a terminal 25. On the printed circuit board 2, the internal element 20 is connected with the terminal 25, and the lead wire 21 is connected to the wire that connects the element 20 and the terminal 25. The lead wire 21 is extended to form the first edge 23 with an exposed copper. Further, corresponds to the first edge 23, the second edge 24 with an exposed copper is formed to further connect to the ground wire 22. If the printed circuit board 2 is designed to be a multiplayer PCB, a throughhole in the PCB can be constructed to establish wire connection to a ground level. By providing the pair of the first edges 23 and the second edges 24, electrostatic discharge of the PCB can be arbitrarily carried out between the lead wire 21 and the ground wire 22.

When the terminal 25 meets some static charge accumulation, the static charges may flow to the first edge 23 via the way a, so as to have the charges be discharged through the copper of the first edge 23 to the correspond second edge 24. Upon such an arrangement, the static charges can be discharged and a possible electrostatic damage upon the internal element 20 can be avoided.

The characteristic of the above invention is laid in using the edge with an exposed copper to perform the static discharge. Preferably, keeping the spacing between the first edge 23 and the second sharp edge 24 at approximately 0.05 mm to 0.1 mm can help to achieve a better static discharge protection effect. In the present invention, edge shape for the first edge 23 or the second edge 24 may be a triangle or a lanceolar. Also, the exposed copper at the edge 23 or 24 can be shaped as a quadrangle diamond shape with one end to connect with the lead wire and another end to space from the other edge for achieving effect of point discharging. In another embodiment, wires of the printed circuit board can be formed by the etching copper foil formation. Generally, the etching coppers are covered by a solder mark to avoid oxidation, but the wire 21 or 22 must expose the edge 23 or 24, respectively, to form the electrostatic discharge pair of the present invention. Preferably, the edge 23 and 24 may be plated with silver to enhance a better electrostatic discharge protection.

Referring to FIG. 2a, FIG. 2b and FIG. 2c, various embodiments of the electrostatic discharge pair of the present invention are shown. The electrostatic discharge pair in FIG. 2a is formed as a quadrangle pair, that in FIG. 2b is formed as a fork pair, and that in FIG. 2c is formed as a saw-tooth pair. In all three embodiments above, the first edge 23 and the second edge 24 are spaced by a predetermined spacing, preferably ranged from 0.05 mm to 0.1 mm. By providing the pair of the first edge 23 and the second edge 24, electrostatic discharge of the PCB can be arbitrarily carried out between the lead wire 21 and the ground wire 22.

Advantages of this invention over the prior art are listed as follows.

1. The formation of the electrostatic discharge pair can be simultaneously formed in a particular etching process in forming the PCB. No extra cost and particular step are needed to form the pair.

2. In one electrostatic discharge pair, multiple point discharging sub-pairs can be formed to enhance the electrostatic discharge protection of the present invention, for example two sub-pairs shown in FIG. 2b and three in FIG. 3c.

3. Because no electrostatic discharge element is required in the present invention, space in the PCB can be released and thus minimization upon the electronic device can be easily achieved.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

I claim:

1. A printed circuit board (PCB) with electrostatic discharge protection, comprising:
a lead wire disposed on the printed circuit board, the lead wire having a first edge with an exposed copper; and
a ground wire disposed on the printed circuit board, the ground wire having a second edge with another exposed copper, in which the first edge separates from the second edge by a predetermined spacing to form an electrostatic discharge pair for arbitrarily carrying out electrostatic discharging between the lead wire and the ground wire.

2. The printed circuit board (PCB) with electrostatic discharge protection according to claim 1, wherein said predetermined spacing is ranged from 0.05 mm to 0.1 mm.

3. The printed circuit board (PCB) with electrostatic discharge protection according to claim 2, wherein said first edge and said second edge are formed as a pair of triangle shapes.

4. The printed circuit board (PCB) with electrostatic discharge protection according to claim 2, wherein said first edge and said second edge are formed as a pair of lanceolar shapes.

5. The printed circuit board (PCB) with electrostatic discharge protection according to claim 2, wherein said first edge and said second edge are formed as a pair of saw-tooth shapes.

6. The printed circuit board (PCB) with electrostatic discharge protection according to claim 5, wherein said saw-tooth shapes are complementary protruding and concavity.

7. The printed circuit board (PCB) with electrostatic discharge protection according to claim 2, wherein said first edge and said second edge are formed as a pair of fork shapes.

8. The printed circuit board (PCB) with electrostatic discharge protection according to claim 1, wherein said both exposed coppers are further plated with silver.
